(19) United States
(12) Patent Application Publication
(10) Pub. No.: US 2025/0341019 A1
(43) Pub. Date: Nov. 6, 2025

(54) ENVELOPE AND ISOLATION PLATE FOR IR TRANSMISSION ADJUSTMENT

(71) Applicant: Applied Materials, Inc., Santa Clara, CA (US)

(72) Inventors: Zhepeng CONG, San Jose, CA (US); Tao SHENG, Santa Clara, CA (US); Nimrod SMITH, Cupertino, CA (US); Benjamin Ean THAM, Elk Grove, CA (US); Gracia Maria COSENZA, San Jose, CA (US); Neil WARKE, Saratoga, CA (US)

(21) Appl. No.: 19/200,122

(22) Filed: May 6, 2025

Related U.S. Application Data
(60) Provisional application No. 63/643,000, filed on May 6, 2024.

(51) Int. Cl. C30B 25/10; C30B 25/08; C30B 25/12; C30B 25/14

(52) U.S. Cl. CPC C30B 25/105; C30B 25/08; C30B 25/12; C30B 25/14

(57) ABSTRACT

Embodiments of the disclosure provided herein include an apparatus and method for tuning the thermal profile on a substrate in the semiconductor processing chamber. The substrate processing chamber includes an upper body defining a processing volume, a heat source configured to heat the processing volume, a substrate envelope assembly disposed within the processing volume, and a substrate support assembly disposed within the substrate envelope assembly. The substrate processing chamber may also include a heat source disposed above the substrate support assembly and coupled to the upper body, an isolation plate assembly disposed between the substrate support assembly and the heat source, and a substrate envelope assembly. The substrate processing system may also include a pre-heat cylinder, the pre-heat cylinder includes a first replaceable portion with one or more inlet openings and a second replaceable portion with one or more outlet openings.

### CROSS-REFERENCE TO RELATED APPLICATION

This application claims the benefit of and priority to U.S. Provisional Patent Application No. 63/643,000, filed May 6, 2024, which is incorporated by reference herein in its entirety.

### BACKGROUND

### Field

Embodiments of the present disclosure generally relate to semiconductor processing chambers, and more particularly, to apparatus and methods for processing chamber thermal profile tuning.

### Description of the Related Art

Semiconductor substrates are processed for a wide variety of applications, including the fabrication of integrated devices and micro-devices. One method of processing substrates includes depositing a material, such as a dielectric material or a semiconductive material, on an upper surface of the substrate. The material may be deposited in a lateral flow chamber by flowing a process gas parallel to the surface of a substrate positioned on a support, and thermally decomposing the process gas to deposit a material from the gas onto the substrate surface. However, the material deposited on the surface of the substrate can be non-uniform in thickness, and therefore, negatively affect the performance of the manufactured device.

It can be difficult to adjust parameters for deposition uniformity, particularly for low temperature epitaxy processes, such as processes using a cold wall reactor. It can also be difficult to activate gases for deposition. Rotation of the substrate, if used, can exacerbate adjustment difficulties. Relatively low rotation speeds, high pressures, and low flow rates can also exacerbate adjustment difficulties.

Accordingly, there is a need for improved process chamber components and related methods that facilitate depositing a film that is more uniform in thickness.

### SUMMARY

Embodiments herein are generally directed to semiconductor processing chambers and, more particularly, to systems and methods for tuning the thermal profile on a substrate in the semiconductor processing chamber.

In an embodiment, a substrate processing chamber is provided. The substrate processing chamber includes an upper body defining a processing volume, a heat source configured to heat the processing volume, a substrate envelope assembly disposed within the processing volume, and a substrate support assembly disposed within the substrate envelope assembly.

In another embodiment, a substrate processing chamber is provided. The substrate processing chamber includes a chamber body defining a processing volume, a substrate support assembly disposed within the processing volume, a heat source disposed above the substrate support assembly and coupled to the chamber body, an isolation plate assembly disposed between the substrate support assembly and the heat source, and a substrate envelope assembly, the substrate support assembly disposed within the substrate envelope assembly.

In another embodiment, a method of processing a substrate is provided. The method includes placing a substrate on a substrate support assembly coupled to a lower envelope plate, elevating the substrate support assembly into an elevated processing position, and applying infrared radiation from an infrared radiation source to the substrate.

In another embodiment, a substrate processing chamber is provided. The substrate processing system includes a chamber body defining a processing volume, a substrate support assembly disposed within the processing volume, a heat source disposed above the substrate support assembly and coupled to the chamber body, an isolation plate assembly disposed between the substrate support assembly and the heat source, and a pre-heat cylinder. The pre-heat cylinder includes a first replaceable portion with one or more inlet openings and a second replaceable portion with one or more outlet openings.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and the present disclosure may admit to other equally effective embodiments.

FIG. 1 is a partial schematic side cross-sectional view of a processing chamber, according to certain embodiments.

FIG. 2 is a partial schematic side cross-sectional view of a processing chamber, according to certain embodiments.

FIG. 3 illustrates a close-up view of a portion of a processing chamber including an isolation plate assembly, according to certain embodiments.

FIG. 4 illustrates a simplified schematic, cross-sectional view of a processing chamber, according to certain embodiments.

FIG. 5A illustrates a schematic, cross-sectional view of a portion of a processing chamber including a substrate envelope, according to certain embodiments.

FIG. 5B illustrates a perspective view of a portion of a processing chamber including a substrate envelope, according to certain embodiments.

FIG. 6 is a partial schematic side cross-sectional view of a processing chamber, according to certain embodiments.

FIG. 7 illustrates a close-up view of a portion of a processing chamber including a pre-heat cylinder, according to certain embodiments.

FIG. 8 illustrates a perspective view of a pre-heat cylinder, according to certain embodiments.

FIG. 9 shows a flow chart illustrating a method of heating a substrate, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed to semiconductor processing chambers and, more particularly, to systems and methods for tuning the thermal profile on a substrate in the semiconductor processing chamber.

Undesired heating profiles in epitaxy can arise from the type and design of lamps used to emit infrared radiation (IR), the distance between the lamp and the substrate, and the shadow effects caused by obstacles within the processing chamber. These heating profiles result in undesired deposition on the substrates being processed. Thermal chemical vapor deposition (CVD) may require uneven heating to compensate for gas activation and gas depletion. The goal in these settings is to grow epitaxy film with reasonable uniformity with substrate rotations. As a result, a uniform thermal profile will not always benefit the epitaxy film uniformity, resulting in a need to adjust the thermal profile, e.g., per recipe, to produce uniform thermal films. Additionally, epitaxial film purity requires a clean interface between the substrate and the substrate support surface and in-film defect- and contamination-free deposition. The cleanliness of processing chambers rely on both large amounts of high-purity purge flow containing H₂ and high temperatures. Semiconductor processes with lower temperatures, e.g., as low as 400° C.; result in reduced film growth rates. In these settings, low temperature H₂ gas flow rate is reduced to increase growth rate. However, the lack of thermal energy and hydrogen flow leads to an unacceptable oxygen level in the epitaxy film.

The present disclosure provides for a processing chamber to improve the thermal profile on a substrate where the processing chamber includes an isolation plate assembly. The isolation plate assembly provides thermal tuning by providing one or more isolation materials configured to absorb or reflect different amounts of infrared radiation on different portions of the isolation plate assembly to produce a desired thermal profile over a substrate. The present disclosure also provides for a processing chamber with a substrate envelope assembly configured to provide additional thermal tuning through the material and structure of the envelope to improve heating efficiency in low temperature processes while preventing contamination. The present disclosure further provides a processing chamber with a pre-heat cylinder configured to provide easy exchangeable process kit parts to accommodate a range of channels to control gas flow and improve heating efficiency within the processing chamber. The pre-heat cylinder allows for separate heating of the substrate and the processing chamber walls to allow for temperature optimization during processing.

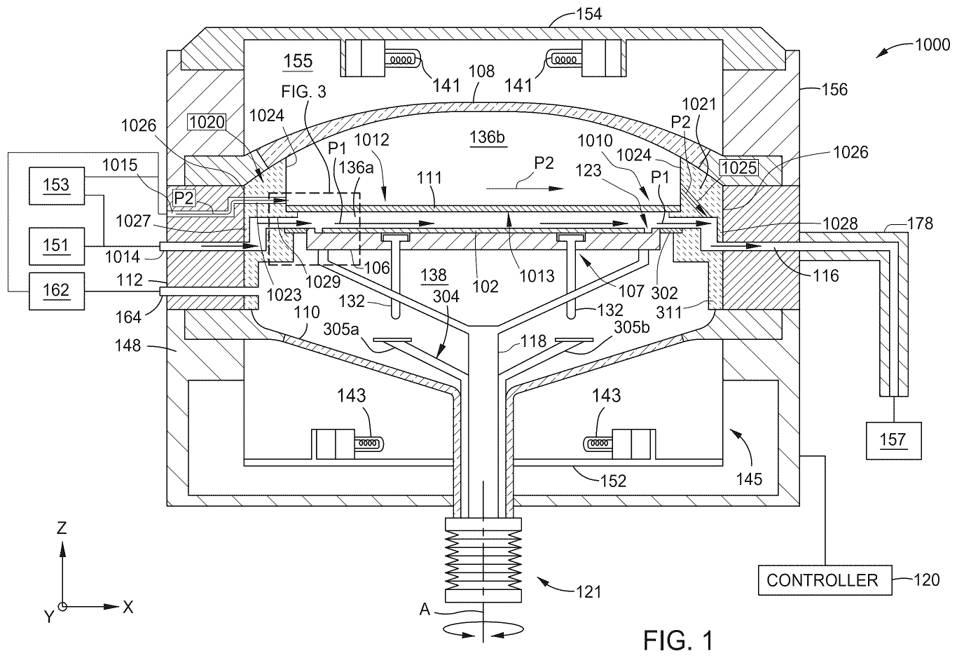

FIG. 1 is a partial schematic side cross-sectional view of a processing chamber 1000, according to one or more embodiments. The processing chamber 1000 is a deposition chamber. In one or more embodiments, the processing chamber 1000 is an epitaxial deposition chamber. In one or more embodiments, the processing chamber 1000 is utilized to grow an epitaxial film on a substrate 102. The processing chamber 1000 creates a single-pass flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support assembly 106, an upper window 108 (such as an upper dome), a lower window 110 (such as a lower dome), a plurality of upper heat sources 141, and a plurality of lower heat sources 143. As shown, a controller 120 is in communication with the processing chamber 1000 and is used to control processes and methods, such as the operations of the methods described herein. The present disclosure contemplates that each of the heat sources described herein can include one or more of: infrared radiation sources, lamps, resistive heaters, light emitting diodes (LEDs), lasers, or a combination thereof. The present disclosure contemplates that other heat sources can be used.

The substrate support assembly 106 is disposed between the upper window 108 and the lower window 110. The substrate support assembly 106 includes a support face 123 that supports the substrate 102. The plurality of upper heat sources 141 are disposed between the upper window 108 and a lid 154. The plurality of upper heat sources 141 form a portion of an upper heat source module 155 and are configured to heat a processing volume 136 of the processing chamber 1000. The lid 154 may include a plurality of sensors (not shown) disposed therein or thereon for measuring the temperature within the processing chamber 100. The plurality of lower heat sources 143 are disposed between the lower window 110 and a floor 152. The plurality of lower heat sources 143 form a portion of a lower heat source module 145 and are configured to heat the processing volume 136 of the processing chamber 1000. In one or more embodiments, the upper window 108 is an upper dome and is formed of an energy transmissive material, such as quartz. In one or more embodiments, the lower window 110 is a lower dome and is formed of an energy transmissive material, such as quartz. A pre-heat ring 302 is disposed outwardly of the substrate support assembly 106. The pre-heat ring 302 is supported on a ledge of a lower liner 311. A stop 304 includes a plurality of arms 305a, 305b that each include a lift pin stop on which at least one of lift pins 132 can rest when the substrate support assembly 106 is lowered (e.g., lowered from a process position to a transfer position).

The processing volume 136 has the substrate support assembly 106 disposed therein. The substrate support assembly 106 includes a top surface on which the substrate 102 is disposed. The substrate support assembly 106 is attached to a shaft 118. The shaft 118 is connected to a motion assembly 121. The motion assembly 121 includes one or more actuators and/or adjustment devices that provide movement and/or adjustment for the shaft 118 and/or the substrate support assembly 106.

The substrate support assembly 106 may include lift pin perforations 107 disposed therein. The lift pin perforations 107 are sized to accommodate a lift pin 132 for lifting of the substrate 102 from the substrate support assembly 106 either before or after a deposition process is performed.

A process kit 1010 includes an isolation plate 111 having a first outer face 1012 and a second outer face 1013 opposing the first outer face 1012. The second outer face 1013 faces the substrate support assembly 106. The process kit 1010 includes an upper liner 1020. The upper liner 1020 includes an annular section 1021. The upper liner 1020 includes one or more inlet openings 1023 extending to an inner surface 1024 of the annular section 1021 on a first side of the upper liner 1020, and one or more outlet openings 1025 extending to the inner surface 1024 of the annular section 1021 on a second side of the upper liner 1020. The one or more outlet openings 1025 fluidly connect the upper portion 136b of the processing volume to the gas exhaust outlets 116 to evacuate gases from the upper portion 136b.

The one or more inlet openings 1023 extend from an outer surface 1026 of the annular section 1021 of the upper liner 1020 to the inner surface 1024. The one or more outlet openings 1025 extend from a lower surface 1029 of the upper liner 1020 to the inner surface 1024. The upper liner 1020 includes a first extension 1027 and a second extension 1028 disposed outwardly of a lower surface 1029 of the upper liner 1020. At least part of the annular section 1021 of the upper liner 1020 is aligned with the first extension 1027 and the second extension 1028. In the embodiment shown in FIG. 1, a lowermost end of the isolation plate 111 is aligned above a lowermost end of the upper liner 1020. In one or more embodiments, as shown in FIG. 1, the lowermost end of the isolation plate 111 is part of the second outer face 1013, and the lowermost end of the upper liner 1020 is part of the first extension 1027 and/or the second extension 1028. The present disclosure contemplates that the lowermost end of the upper liner 1020 can be part of the lower surface 1029.

The isolation plate 111 is in the shape of a disc, and the annular section 1021 is in the shape of a ring. It is contemplated, however, that the isolation plate 111 and/or the annular section 1021 can be in the shape of a rectangle, or other geometric shapes. The isolation plate 111 at least partially fluidly isolates an upper portion 136b of the processing volume from a lower portion 136a of the processing volume 136.

The flow module 112 (which can define at least part of one or more sidewalls of the processing chamber 1000) includes one or more first inlet openings 1014 in fluid communication with the lower portion 136a of the processing volume. The flow module 112 includes one or more second inlet openings 1015 in fluid communication with the upper portion 136b of the processing volume. The one or more first inlet openings 1014 are in fluid communication with one or more flow gaps between the upper liner 1020 and the lower liner 311. The one or more second inlet openings 1015 are in fluid communication with the one or more inlet openings 1023 of the upper liner 1020. The first inlet openings 1014 are fluidly connected to one or more process gas sources 151 and one or more cleaning gas sources 153. The one or more second inlet openings are in fluid communication with the one or more cleaning gas sources 153 and one or more purge gas sources 162. Purge gas inlets 164 are fluidly connected to the one or more purge gas sources 162. One or more gas exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen and/or chlorine. In one embodiment, which can be combined with other embodiments, the one or more process gases include silicon phosphide (SiP) and/or phosphine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 1000 relative to the flow module 112.

In one or more embodiments, as shown in FIG. 1, the one or more inlet openings 1023 are oriented in a horizontal orientation and the one or more outlet openings 1025 are oriented in an angled orientation. The present disclosure contemplates that the one or more of the inlet openings 1023 or outlet openings 1025 can be oriented in a horizontal orientation, oriented in an angled (e.g., non-parallel to horizontal) orientation, and/or can include one or more turns (such as the turns shown for the one or more first inlet openings 1014 and the one or more gas exhaust outlets 116).

During a deposition operation (e.g., an epitaxial growth operation), one or more process gases P1 flow through the one or more first inlet openings 1014, through the one or more gaps, and into the lower portion 136a of the processing volume to flow over the substrate 102. During the deposition operation, one or more purge gases P2 flow through the one or more second inlet openings 1015, through the one or more inlet openings 1023 of the upper liner 1020, and into the upper portion 136b of the processing volume. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through gaps between the upper liner 1020 and the lower liner 311, and through the one or more gas exhaust outlets 116. The one or more purge gases P2 are exhausted through the one or more outlet openings 1025, through the same gaps between the upper liner 1020 and the lower liner 311, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

The present disclosure also contemplates that one or more purge gases can be supplied to a purge or lower chamber volume 138 (through the plurality of purge gas inlets 164) during the deposition operation, and exhausted from the lower chamber volume 138.

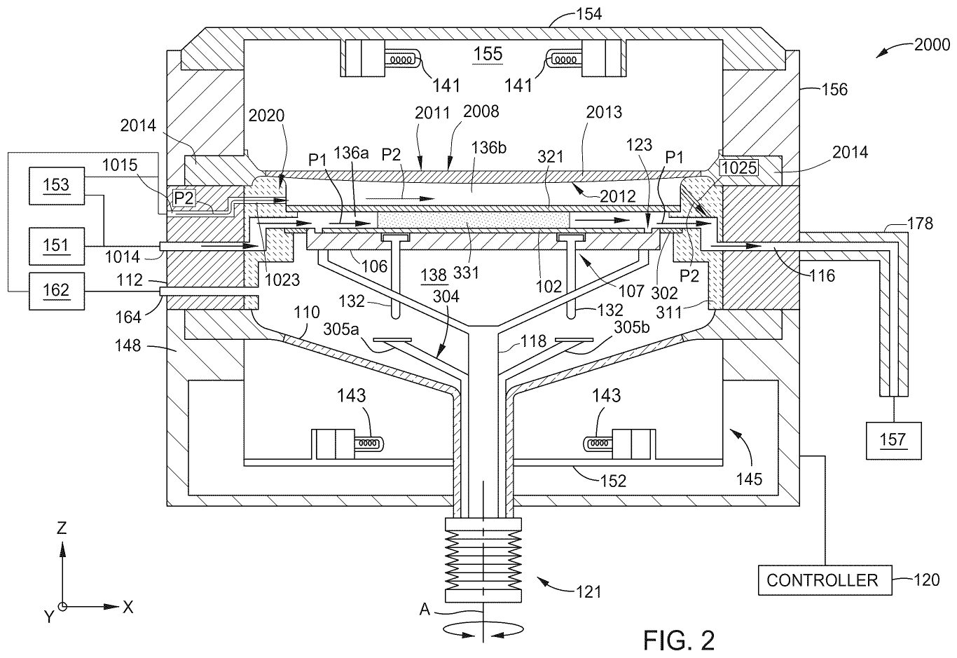

FIG. 2 is a partial schematic side cross-sectional view of a processing chamber 2000, according to one or more embodiments. The processing chamber 2000 is similar to the processing chamber 1000 shown in FIG. 1, and includes one or more of the aspects, features, components, properties, and/or operations thereof. The processing chamber 2000 is shown in a processing condition in FIG. 2.

The processing chamber 2000 includes a window 2008 that at least partially defines the processing volume. The window 2008 includes a first face 2011 that is concave or flat (in the embodiment shown in FIG. 2, the first face 2011 is flat). The window 2008 includes a second face 2012 that is convex. The second face 2012 faces the substrate support assembly 106.

The processing chamber 2000 includes a liner 2020. The liner 2020 is similar to the upper liner 1020 shown in FIG. 1, and includes one or more of the aspects, features, components, properties, and/or operations thereof. A first block 331 and a second block (not shown) are oriented parallel to each other. The first block 331 is disposed below the isolation plate 321 and above the substrate support assembly 106. The first block 331 assists with flow of process gas P1 over the substrate 102 to facilitate improving deposition uniformity. In one or more embodiments, the isolation plate 321 and the first block 331 are supported by and/or coupled to the liner 2020 and/or the pre-heat ring 302. In one or more embodiments, the isolation plate 321 and the first block 331 rest on the upper liner 1020 and/or the pre-heat ring 302.

The window 2008 includes an inner section 2013 and an outer section 2014. The first face 2011 and the second face 2012 are at least part of the inner section 2013. In one or more embodiments, the inner section 2013 is transparent and the outer section 2014 is opaque. The outer section 2014 is received at least partially in one or more sidewalls (such as in the flow module 112 and/or the upper body 156) of the processing chamber 2000.

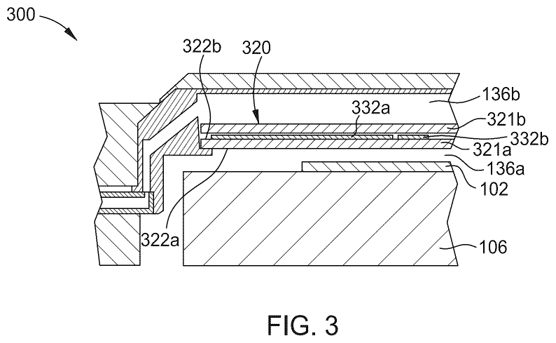

FIG. 3 illustrates a close-up view of a portion 300 of the processing chamber 1000 including an isolation plate assembly 320, according to certain embodiments. Alternatively, the portion 300 may be a portion of the processing chamber 2000, according to certain embodiments.

Undesired heating profiles in epitaxy can arise from the type and design of lamps used the upper heat sources 141 and the lower heat sources 143, such as infrared radiation sources, to emit infrared radiation (IR). For example, halogen lamps may feature “hot spots” near the filament, while certain LED arrays might display slightly brighter or dimmer zones resulting in uneven heating on the substrate. Additionally, the distance between the lamp and the substrate directly influences heating intensity and uniformity. Placing the lamp too close can generate hot spots, while positioning it too far away may result in insufficient heating and compromised film quality. Obstacles within the reactor, such as gas inlets or support structures, can cast shadows on the substrate, blocking radiation and leading to colder areas and create a shadow effect. Collectively, these effects may lead to non-uniform film deposition on the substrate. Thus, adjusting the heating profile is often needed for a specific epitaxy process.

As such, a processing chamber, e.g., the processing chamber 1000 or the processing chamber 2000, may include an isolation plate assembly 320 to achieve a desired thermal profile on a substrate 102.

As shown in FIG. 3, the isolation plate assembly 320 is disposed between the lower portion 136a and the upper portion 136b of the processing volume. The substrate 102 is disposed on the substrate support assembly 106 in the processing volume 136. The isolation plate assembly 320 includes a lower isolation plate 321a having a processing surface 322a that faces the substrate 102 in the processing volume 136 and an isolation surface 322b that opposes the processing surface 322a. One or more isolation materials, such as a first isolation material 332a and a second isolation material 332b, may be disposed on the isolation surface 322b of the lower isolation plate 321a. Optionally, an upper isolation plate 321b may be disposed over the lower isolation plate 321a, the first isolation material 332a, and the second isolation material 332b such that the isolation materials, e.g., the first isolation material 332a and the second isolation material 332b, and the isolation surface 322b are not exposed to the processing volume 136. The addition of the upper isolation plate 321b allows the formation of a thermal filter cavity to accommodate different IR transmission or absorption material, e.g., the one or more isolation materials, to further tune the thermal profile through the isolation plate assembly 320.

The lower isolation plate 321a and the upper isolation plate 321b may be made of IR-transparent materials, such as quartz. Optionally, the IR transparent materials may be selectively transparent to desired IR wavelengths, e.g., by adjusting the hydroxide content of quartz or by adjusting the thickness of the materials. This allows the IR radiation emitted by the upper heat sources 141, the lower heat sources 143, or both to penetrate the lower isolation plate 321a and the upper isolation plate 321b such that the IR radiation is only absorbed or reflected by the isolation materials, e.g., the first isolation material 332a and the second isolation material 332b. This allows for the first isolation material 332a and the second isolation material 332b to define a desired thermal profile on the substrate 102 without interference by the lower isolation plate 321a or the upper isolation plate 321b.

The isolation materials, e.g., the first isolation material 332a and the second isolation material 332b, may be made of materials with different infrared radiation transmissivity, e.g., materials that absorb or reflect different amounts of infrared radiation. For example, the isolation materials may be silicon (Si) or silicon carbide (SIC). Further, different thermal profiles may be made by using variations of the isolation materials, such as polymorphs of the same material. For example, the first isolation material 332a may include 4H SiC and the second material may include 6H SiC or a 3C SiC to achieve IR transmission as low as about 10% to about 15%. The first isolation material 332a and the second isolation material 332b may be arranged in a pattern, such as a honeycomb pattern or array, to alter the IR radiation that reaches the substrate 102. For example, the first isolation material 332a and the second isolation material 332b may be configured to allow less IR radiation to an edge of the substrate 102 while allowing more IR radiation to an opposing edge of the substrate 102. Optionally, there may be more isolation materials, e.g., a third isolation material (not shown), to further tune the thermal profile produced on the substrate 102 by the upper heat sources 141, the lower heat sources 143, or both.

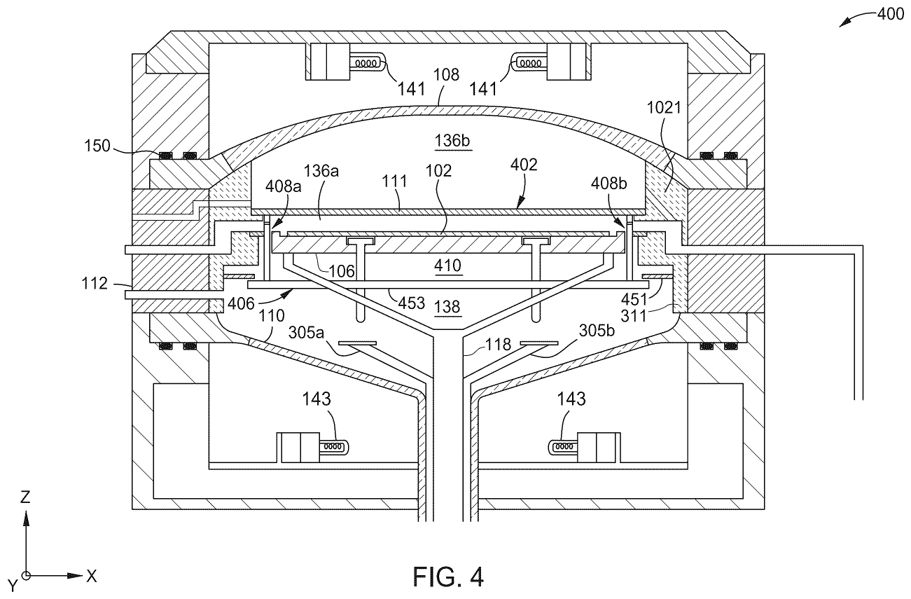

FIG. 4 illustrates a simplified schematic, cross-sectional view of a processing chamber 400 configured similarly to the processing chamber 1000, according to certain embodiments. Alternatively, the processing chamber 400 may be configured similarly to the processing chamber 2000, according to certain embodiments.

Epitaxial film purity can only be achieved with an ultra-clean reactor to ensure clean interface and in-film defect- and contamination-free deposition, such as in a molecular-beam epitaxy system with an ultra-high vacuum environment. An ultra-high vacuum system, however, requires a long period of time to reach an ultra-vacuum state, making it difficult to incorporate into semiconductor manufacturing processes requiring high throughput. Additionally, gaskets, such as O-rings or other elastomer seals, are used to seal processing chambers but have high permeability that allow air contamination to enter. As such, the cleanliness of current epitaxial processing chambers rely on both large amounts of high-purity purge flow containing H₂ and high temperatures. In semiconductor processes with lower temperatures, e.g., as low as 400° C., film growth rates are reduced due to the lower temperatures. As such, low temperature H₂ gas flow is used to increase growth rate. Additionally, a separate gas activation source is added, such as ultraviolet light, plasma, or microwave, as the lack of thermal energy and hydrogen flow struggle to prevent oxygenation of the substrate. As such, a substrate envelope assembly 402 may be used to address these issues.

As shown in FIG. 4, a substrate 102 is disposed on a substrate support assembly 106 in the lower portion 136a of the processing volume. The lower portion 136a of the processing volume is sealed by gaskets 150 between the upper window 108, the annular section 1021 and/or the flow module 112, and the lower window 110. The substrate 102 and the substrate support assembly 106 are enclosed by the substrate envelope assembly 402. The substrate envelope assembly 402 includes the isolation plate 111, a lower envelope plate 406, and sidewalls 408, e.g., a first sidewall 408a and a second sidewall 408b, to define an envelope volume 410. The lower envelope plate 406 includes a disk 451 and ring 453 disposed in the lower chamber volume 138 between the lower window 110 and the substrate support assembly 106. More specifically, the disk 451 is positioned opposite and parallel to the substrate support assembly 106 and extends across the lower chamber volume 138. In one embodiment, the disk 451 is coupled to arms 420 that extend radially outward from the shaft 118. The disk 451 includes a plurality of holes formed therein and positioned to enable the lift pins 424 to extend therethrough. Similarly, the disk 451 includes a plurality of holes or slots through which the arms 420 extend. In such a manner, the disk 451 is coupled to the arms 420 and the disk 451 is capable of moving vertically (e.g. up and down within the lower chamber volume 138) and rotating about a central axis defined by the shaft 118. In one embodiment, the disk 451 fabricated from a single piece of material. In another embodiment, the disk 451 is fabricated from multiple pieces and arranged about the arms 420 such that the disk 451 functions substantially like a solid material when installed within the lower chamber volume 138.

The ring 453 is positioned within the lower chamber volume 138 adjacent to the disk 451 when the substrate support assembly 106 is in an elevated processing position. In one embodiment, the ring 453 is positioned at an elevation above any elevation occupied by the disk 451. The ring 453 is coupled to and extends radially inward from the lower liner 311. The disk 451 has a diameter which is greater than an inner diameter of the ring 453 such that the disk 451 and the ring 453 overlap one another. An outer diameter of the ring 453 is greater than the diameter of the disk 451. The overlapping of the disk 451 and ring 453 enables further control of process and purge gas management within the lower chamber volume 138. For example, purge gas introduced into the lower chamber volume 138 may be maintained below the disk 451 and ring 453. A pressure differential above and below the disk 451/ring 453 overlapping further prevents process gasses from traveling further within the lower chamber volume 138 and depositing on surfaces of the chamber, such as the lower window 110.

In one embodiment, the disk 451 and the ring 453 are fabricated from a quartz material. In this embodiment, the quartz material is a low OH quartz material with an OH content of less than about 30 parts per million (ppm), such as less than about 15 ppm, such as about 5 ppm or less. The transmission rate of the quartz material for a desired wavelength is greater than about 90%, such as greater than about 95%, for example, greater than about 98%. In another embodiment, the disk 451 and the ring 453 are fabricated from different materials. For example, the disk 451 is formed from the low OH quartz material and the ring 453 is formed from opaque or black quartz. In this embodiment, the disk 451 would enable the transmission of light therethrough while the ring 453 would function to stop the transmission of light therethrough. In another embodiment, the disk 451 is fabricated from the low OH quartz material and the disk 451 is fabricated from a ceramic material, such as silicon carbide or the like.

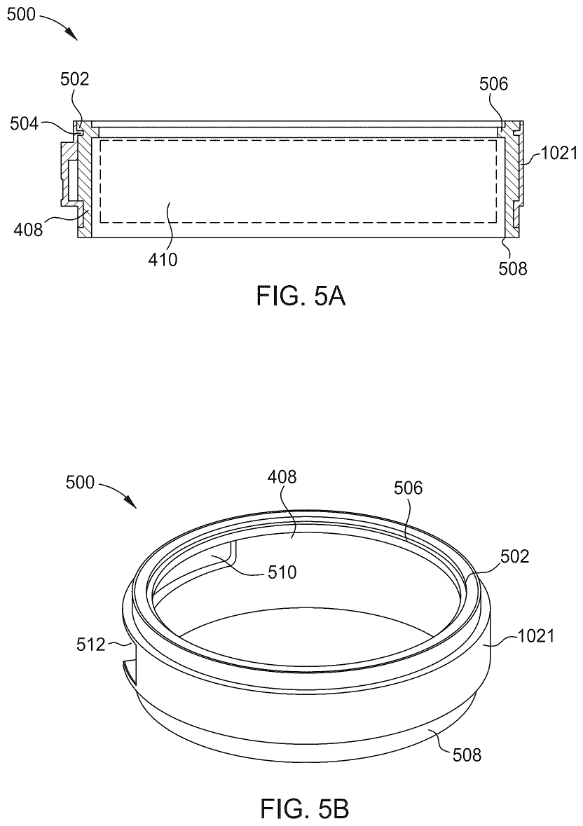

FIG. 5A illustrates a schematic, cross-sectional view of a portion 500 of a processing chamber, e.g., the processing chamber 400, including a substrate envelope assembly, e.g., the substrate envelope assembly 402, according to certain embodiments. FIG. 5B illustrates a perspective view of the portion 500, according to certain embodiments.

As shown in FIG. 5A, the sidewalls 408 of the substrate envelope assembly 402 include an annular hot wall flange 502 configured to rest or couple to a cold wall flange 504 of the annular section 1021. The sidewalls 408 also include a upper lip 506 configured to removably couple to an isolation plate, e.g., the isolation plate 111, to create a seal at the top of the envelope volume 410. The sidewalls 408 include a lower lip 508 configured to contact the lower envelope plate 406 to create a seal at the bottom of the envelope volume 410.

As shown in FIG. 5B, the sidewalls 408 of the substrate envelope assembly 402 may include a hot wall aperture 510 that coincides with or overlaps a cold wall aperture 512 of the annular section 1021. The hot wall aperture 510 and the cold wall aperture 512 allow for process gases to enter the envelope volume 410 and access a substrate disposed therein.

The isolation plate 111 is removably coupled to the lower envelope plate 406 by the sidewalls 408, e.g., sealing the envelope volume 410 when a substrate support assembly, e.g., the substrate support assembly 106, is in a raised position and unsealing the envelope volume 410 when the substrate support assembly 106 is in a lowered position, such that a substrate disposed on the substrate support assembly 106 may be transferred in and out of the envelope volume 410. The sidewalls 408 are configured to minimize gas exchange between the envelope volume 410 and a processing volume, e.g., the processing volume 136. When sealed, the envelope volume 410 also provides thermal isolation of the substrate envelope assembly 402 to maintain a lower temperature within the envelope volume 410 that the processing volume 136, allowing for more efficient cooling of the substrate during low temperature epitaxy processes.

The isolation plate 111 and the lower envelope plate 406 may include materials that are semi-transparent to IR radiation. Semi-transparent materials may be defined as materials that transmit a desired IR wavelength range while filtering or absorbing undesired IR wavelengths. The sidewalls 408 may include semi-transparent materials or materials that are not transparent to IR radiation or materials with low IR transmissivity. For example, the sidewalls 408 may include low IR transmissive materials, such as amorphous silica, silicon carbide (SiC), or SiC-coated graphite.

Using IR semi-transparent materials for the isolation plate 111 and the lower envelope plate 406 allows for IR radiation to enter the envelope volume 410. Use of lower IR transmissive materials for the sidewalls 408 allows for thermal isolation between the envelope volume 410 and the processing volume 136 such that IR radiation does not radiate from the envelope volume 410 through the sidewalls 408 into the processing volume 136 and through the upper body 156 and/or the flow module 112, e.g., via the upper liner 1020.

The configuration described in FIG. 4 allows for the substrate envelope assembly 402 to transform what would be a cold wall reactor to a hot wall reactor, particularly for low processing temperatures, such as temperatures between about 400° C. and about 450° C., resulting in improved film quality and growth rate during epitaxial processing.

Additionally, the substrate envelope assembly 402 allows for isolation of the substrate support assembly 106 from the cleaning gases flowed by the flow module 112, e.g., HCl or Cl₂. Flowing chlorine-containing gases over a substrate support assembly 106 that comprises iron, e.g., stainless steel, at elevated temperatures will produce volatile salts including iron chloride, e.g., FeCl₂ or FeCl₃, which will contaminate the substrate 102 when placed onto the substrate support assembly 106. The substrate envelope assembly 402 isolates the substrate support assembly 106 from the flow of these cleaning gases, reducing iron chloride contamination on the substrate 102.

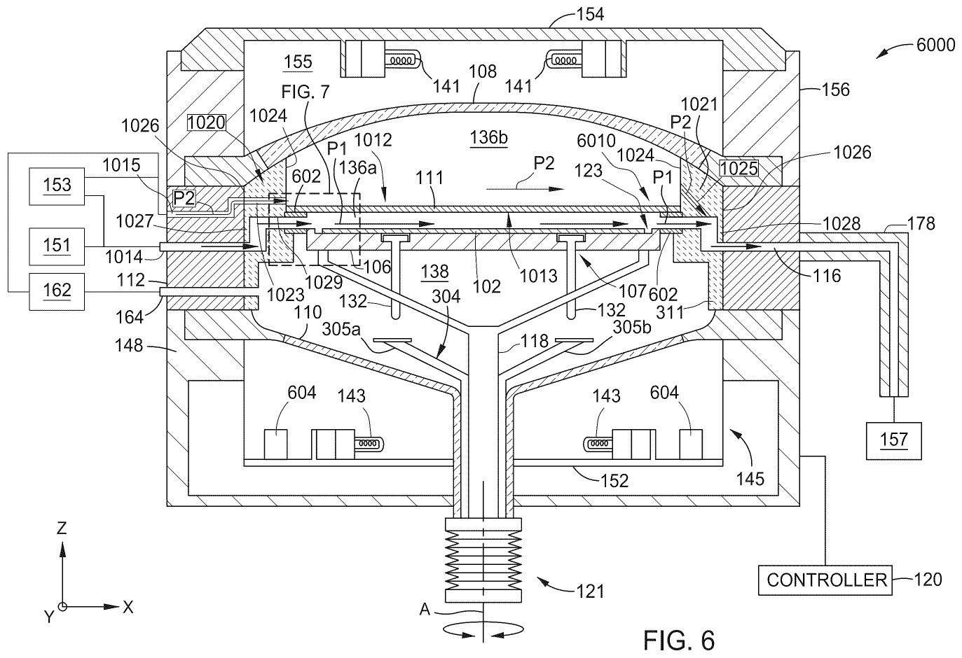

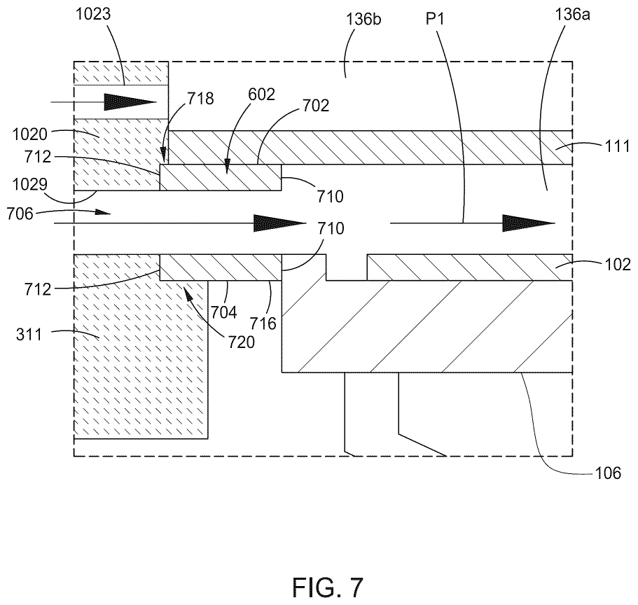

FIG. 6 is a partial schematic side cross-sectional view of a processing chamber 6000, according to one or more embodiments. The processing chamber 6000 includes a processing kit 6010. The process kit 6010 includes at least a pre-heat cylinder 602 and an isolation plate 111. The processing chamber 6000 is a deposition chamber. In one or more embodiments, the processing chamber 6000 is an epitaxial deposition chamber. In one or more embodiments, the processing chamber 6000 is utilized to grow an epitaxial film on a substrate 102. The processing chamber 6000 creates a single-pass flow of precursors across a top surface of the substrate 102. The processing chamber 6000 is shown in a processing condition in FIG. 6. FIG. 7 shows a close-up view of a portion of a processing chamber including a pre-heat cylinder 602, according to one or more embodiments. Specifically, FIG. 7 shows a close-up view of the process kit 6010 that includes the pre-heat cylinder 602.

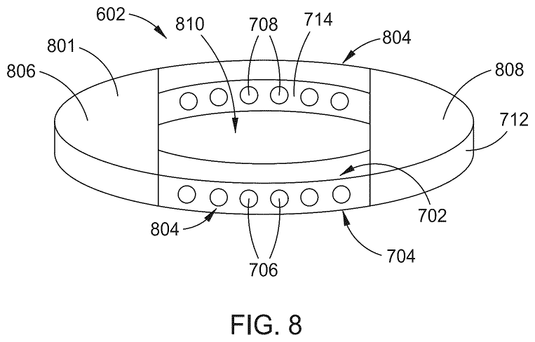

FIG. 8 a perspective view of a pre-heat cylinder 602, according to certain embodiments. In one or more embodiments, the pre-heat cylinder 602 comprises or is silicon carbide (SiC). The silicon carbide may be coated in graphite. In one or more embodiments, the pre-heat cylinder 602 includes an annular body 801. The annular body 801 includes an inner surface 710 for facing the substrate 102 being processed and an outer surface 712 for facing the lower body 148 or the flow module 112. The inner surface 714 defines a processing volume 810 in which a substrate is processed. The processing volume 810 may be the processing volume 136. During processing, the processing volume 810 is part of the hot envelope. The pre-heat cylinder 602 further includes an upper surface 702 for contacting the isolation plate 111. The upper surface 702 couples the inner surface 710 with the outer surface 712. The pre-heat cylinder 602 further includes a lower surface 704 opposite the upper surface 702 for contacting the substrate support assembly 106. The lower surface 704 couples the inner surface 710 with the outer surface 712.

The annular body 801 includes a gas injection portion 802, a gas exhaust portion 804, a first solid portion 806, and a second solid portion 808. The gas injection portion 802 and the gas exhaust portion 804 are opposite each other along the annular body 801 of the pre-heat cylinder 602. Between the gas injection portion 802 and the gas exhaust portion 804 are at least a first solid portion 806 and a second solid portion 808. The first solid portion 806 and the second solid portion 808 are opposite each other along the annular body 801 of the pre-heat cylinder 602.

The gas injection portion 802 includes one or more gas delivery passages 706 for delivering process gas to the processing volume 810 defined by the inner surface 710. The one or more gas delivery passages 706 extend from the outer surface 712 to the inner surface 710 of the annular body 801. The gas exhaust portion 804 includes one or more gas exhaust passages 708 for removing gas from the processing volume 810. The one or more gas exhaust passages 708 extend from the inner surface 710 to the outer surface 712 of the annular body 801. In one or more embodiments, the gas injection portion 802, the gas exhaust portion 804, or both the gas injection portion 802 and the gas exhaust portion 804 are replaceable such that the gas injection portion 802 and the gas exhaust portion 804 are operable to attach and detach from the annular body 801. Each replaceable portion (e.g., the gas injection portion 802 and the gas exhaust portion 804) is operable to be replaced with a different replaceable portion (not pictured). The different replaceable portion may include varying numbers of the gas delivery passages 706 and/or the gas exhaust passages 708, varying sizes of the gas delivery passages 706 and/or the gas exhaust passages 708, varying spacing of the gas delivery passages 706 and/or the gas exhaust passages 708 over the different replaceable portion, or combinations thereof. The gas injection portion 802 and the gas exhaust portion 804 allows for easy process optimization of the processing kit 6010 according to substrate processing needs.

Referring to FIG. 6 and FIG. 7, the one or more gas delivery passages 706 extend through the gas injection portion 802 and the one or more gas exhaust passages 708 extend through the gas exhaust portion 804 to provide fluid communication from the flow module 112 to the processing volume 136. As shown in FIG. 6, the pre-heat cylinder 602 is disposed around at least the substrate support assembly 106 and the substrate 102 during substrate processing operations. The annular body 801 of the pre-heat cylinder 602 defines the processing volume 810 between the gas injection portion 802, the first solid portion 806, the gas exhaust portion 804, and the second solid portion 808. The pre-heat cylinder 602, the isolation plate 111, and the substrate support assembly 106 define the processing volume 810 such that a hot envelope forms around the substrate 102 during processing. Although the substrate support assembly 106 is shown as contacting the pre-heat cylinder 602 to form the hot envelope, in other embodiments, an envelope plate 406 contacts the pre-heat cylinder 602 to form the hot envelope.

Referring to FIG. 6, the processing chamber 6000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support assembly 106, an upper window 108 (such as an upper dome), a lower window 110 (such as a lower dome), a plurality of upper heat sources 141, and a plurality of lower heat sources 143. As shown, a controller 120 is in communication with the processing chamber 6000 and is used to control processes and methods, such as the operations of the methods described herein. The present disclosure contemplates that each of the heat sources described herein can include one or more of: infrared radiation sources, lamps, resistive heaters, light emitting diodes (LEDs), lasers, or a combination thereof. The present disclosure contemplates that other heat sources can be used.

The substrate support assembly 106 is disposed between the upper window 108 and the lower window 110. The substrate support assembly 106 includes a support face 123 that supports the substrate 102. The plurality of upper heat sources 141 are disposed between the upper window 108 and a lid 154. The plurality of upper heat sources 141 form a portion of an upper heat source module 155 and are configured to heat a processing volume 136 of the processing chamber 6000. The lid 154 may include a plurality of sensors (not shown) disposed therein or thereon for measuring the temperature within the processing chamber 100. The plurality of lower heat sources 143 are disposed between the lower window 110 and a floor 152. The plurality of lower heat sources 143 form a portion of a lower heat source module 145 and are configured to heat the processing volume 136 of the processing chamber 6000. In one or more embodiments, the upper window 108 is an upper dome and is formed of an energy transmissive material, such as quartz. In one or more embodiments, the lower window 110 is a lower dome and is formed of an energy transmissive material, such as quartz.

The processing volume 136 has the substrate support assembly 106 disposed therein. The substrate support assembly 106 includes a top surface on which the substrate 102 is disposed. The substrate support assembly 106 is attached to a shaft 118. The shaft 118 is connected to a motion assembly 121. The motion assembly 121 includes one or more actuators and/or adjustment devices that provide movement and/or adjustment for the shaft 118 and/or the substrate support assembly 106.

The substrate support assembly 106 may include lift pin perforations 107 disposed therein. The lift pin perforations 107 are sized to accommodate a lift pin 132 for lifting of the substrate 102 from the substrate support assembly 106 either before or after a deposition process is performed.

The process kit 6010 includes the isolation plate 111. The isolation plate 111 has a first outer face 1012 and a second outer face 1013 opposing the first outer face 1012. The second outer face 1013 faces the substrate support assembly 106. The process kit 6010 further includes the pre-heat cylinder 602. In one or more embodiments, the pre-heat cylinder 602 is disposed between the sidewall of the processing chamber 6000 (such as in the flow module 112 and/or the upper body 156) and the processing volume 136.

Referring to FIG. 7, the pre-heat cylinder 602 includes the one or more gas delivery passages 706 extending from the outer surface 712 to the inner surface 710 of the pre-heat cylinder 602. The pre-heat cylinder 602 includes the one or more gas exhaust passages 708 extending from the inner surface 710 to the outer surface 712 of the pre-heat cylinder 602. The one or more gas delivery passages 706 fluidly connect the flow module 112 to the upper portion 136b of the processing volume 136 to flow process gases into the processing volume 136. The one or more gas exhaust passages 708 fluidly connect the lower portion 136a of the processing volume 136 to the gas exhaust outlets 116 to evacuate gases from the lower portion 136a of the processing volume 136.

In the embodiment shown in FIG. 7 and FIG. 8, the isolation plate 111 is disposed over the upper surface 702 of the pre-heat cylinder 602. In one or more embodiments, the substrate support assembly is aligned with lower surface 704 of the pre-heat cylinder 602. In one or more embodiments, the second extension 716 extends over the substrate support assembly 106 such that a seal is created for the processing volume (e.g., the upper portion 136b of the processing volume 136). The pre-heat cylinder 602 and the isolation plate 111 with a disc shaft design allows for a hot envelope to form around the processing volume 136, which reduces contamination from an o-ring. For example, the hot envelope, in FIG. 6, is defined in the lower portion 136a of the processing volume of the processing chamber 6000.

The position of the pre-heat cylinder 602 in the processing chamber 6000 allows for a laser 604 to heat the pre-heat cylinder with an active heating loop. The separate heat source (e.g., the laser 604) operable to pre-heat the pre-heat cylinder 602 allows for gas activation and reduction of susceptor edge heat loss compensation. The laser 604 may be positioned within the processing chamber 6000 below the processing volume 136, as shown in FIG. 6. The laser 604 is coupled to a controller (e.g., controller 120). The pre-heat cylinder 602 may include a pyrometer operable to monitor the active heating loop. The pre-heat cylinder 602 acts as a temperature controlled side wall for gas activation as well as functioning as a thermal barrier to the cold wall.

In one or more embodiments, as shown in FIG. 6, the process kit 6010 includes an upper liner 1020 and a lower liner 311. As shown in FIG. 7, the upper liner 1020 includes at least a first notch 718, as shown in FIG. 7, such that the pre-heat cylinder 602 aligns within the first notch 718 of the upper liner 1020. The upper liner 1020 includes an annular section 1021. The lower liner 311 includes a second notch 720, as shown in FIG. 8, such that the pre-heat cylinder 602 aligns within the second notch 720 of the lower liner 311. The upper liner 1020 includes one or more inlet openings 1023 extending to an inner surface 1024 of the annular section 1021 on a first side of the upper liner 1020, and one or more outlet openings 1025 extending to the inner surface 1024 of the annular section 1021 on a second side of the upper liner 1020. The one or more outlet openings 1025 fluidly connect the upper portion 136b of the processing volume to the gas exhaust outlets 116 to evacuate gases from the upper portion 136b. In one or more embodiments, the one or more inlet openings 1023 and the one or more outlet openings 1025 of the upper liner 1020 align with the one or more gas delivery passages 706 and the one or more gas exhaust passages 708 of the pre-heat cylinder 602.

The one or more inlet openings 1023 extend from an outer surface 1026 of the annular section 1021 of the upper liner 1020 to the inner surface 1024. The one or more outlet openings 1025 extend from a lower surface 1029 of the upper liner 1020 to the inner surface 1024.

The isolation plate 111 is in the shape of a disc, and the annular section 1021 is in the shape of a ring. It is contemplated, however, that the isolation plate 111 and/or the annular section 1021 can be in the shape of a rectangle, or other geometric shapes. The isolation plate 111 at least partially fluidly isolates an upper portion 136b of the processing volume from a lower portion 136a of the processing volume 136.

The flow module 112 (which can define at least part of one or more sidewalls of the processing chamber 6000) includes one or more first inlet openings 1014 in fluid communication with the lower portion 136a of the processing volume. The flow module 112 includes one or more second inlet openings 1015 in fluid communication with the upper portion 136b of the processing volume. The one or more first inlet openings 1014 are in fluid communication with one or more flow gaps between the upper liner 1020 and the lower liner 311. The one or more second inlet openings 1015 are in fluid communication with the one or more inlet openings 1023 of the upper liner 1020. The first inlet openings 1014 are fluidly connected to one or more process gas sources 151 and one or more cleaning gas sources 153. The one or more second inlet openings are in fluid communication with the one or more cleaning gas sources 153 and one or more purge gas sources 162. Purge gas inlets 164 are fluidly connected to the one or more purge gas sources 162. One or more gas exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen and/or chlorine. In one embodiment, which can be combined with other embodiments, the one or more process gases include silicon phosphide (SiP) and/or phosphine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 6000 relative to the flow module 112.

In one or more embodiments, as shown in FIG. 6, the one or more inlet openings 1023 of the inner liner and/or the one or more gas delivery passages 706 of the pre-heat cylinder 602 are oriented in a horizontal orientation and the one or more outlet openings 1025 of the inner liner and/or the one or more gas exhaust passages 708 of the pre-heat cylinder are oriented in an angled orientation. The present disclosure contemplates that the one or more of the inlet openings 1023, the one or more gas delivery passages 706 or outlet openings 1025, the one or more gas exhaust passages 708 can be oriented in a horizontal orientation, oriented in an angled (e.g., non-parallel to horizontal) orientation, and/or can include one or more turns (such as the turns shown for the one or more first inlet openings 1014 and the one or more gas exhaust outlets 116).

In one or more embodiments, the processing chamber 2000 disclosed in FIG. 2 includes a pre-heat cylinder 602 in place of the pre-heat ring 302. For example, the processing chamber 2000 includes at least a first block 331 disposed below the isolation plate 321 and a pre-heat cylinder 602. The first block 331 disposed below the isolation plate 321 and the pre-heat cylinder 602 provide a processing system operable to optimize the temperature and assist in even gas flow during a processing method. In one or more embodiments, the processing chamber 400 disclosed in FIG. 4 includes a pre-heat cylinder 602 in place of the pre-heat ring 302. For example, the processing chamber 400 includes a substrate envelope assembly 402 and the pre-heat cylinder 602. The substrate envelope assembly 402 and the pre-heat cylinder 602 provide a processing system operable to optimize the temperature during a processing method.

During a deposition operation (e.g., an epitaxial growth operation), one or more process gases P1 flow through the one or more first inlet openings 1014, through the one or more gaps, and into the lower portion 136a of the processing volume to flow over the substrate 102. During the deposition operation, one or more purge gases P2 flow through the one or more second inlet openings 1015, through the one or more inlet openings 1023 of the upper liner 1020, and into the upper portion 136b of the processing volume. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through gaps between the upper liner 1020 and the lower liner 311, and through the one or more gas exhaust outlets 116. The one or more purge gases P2 are exhausted through the one or more outlet openings 1025, through the same gaps between the upper liner 1020 and the lower liner 311, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

The present disclosure also contemplates that one or more purge gases can be supplied to a purge or lower chamber volume 138 (through the plurality of purge gas inlets 164) during the deposition operation, and exhausted from the lower chamber volume 138.

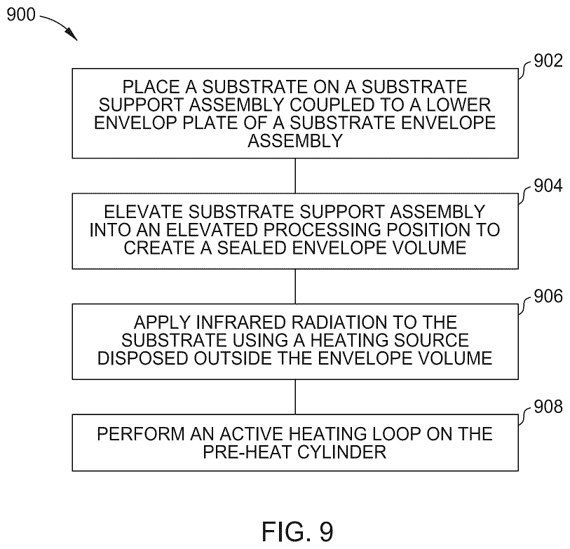

FIG. 9 shows a flow chart illustrating a method 900 of heating a substrate, according to certain embodiments. The method may be performed by the processing chamber 1000, the processing chamber 2000, or the processing chamber 6000. In operation 902, a substrate 102 is placed on a substrate support assembly 106. The substrate support assembly 106 may be coupled to a lower envelope plate 406 as described above regarding FIG. 4. Additionally, the substrate 102 may be disposed under an isolation plate assembly, such as the isolation plate assembly 320 described regarding FIG. 3, such that the isolation plate assembly 320 is disposed between the substrate envelope assembly 402 and the upper heat sources 141, the lower heat sources 143, or both.

In operation 904, the substrate support assembly 106 along with the lower envelope plate 406 is elevated into a processing position such that sidewalls 408 create a sealed envelope volume 410 defined by an isolation plate 111, the sidewalls 408, and the lower envelope plate 406. In this configuration, the substrate disposed on the substrate support assembly 106 is disposed within the envelope volume 410.

In operation 906, infrared radiation is applied to the substrate using the upper heat sources 141, the lower heat sources 143, or both to heat the substrate. The infrared radiation passes through the isolation plate assembly 320 and the portion 500 of the processing chamber 400 then into the envelope volume 410.

In optional operation 908, when the processing chamber (e.g., processing chamber 6000) includes a pre-heat cylinder 602, a laser 604 is used to perform an active heating loop that is monitored by a pyrometer. The laser 604 may be disposed below the processing volume 136. The laser 604 are operable to heat the pre-heat cylinder 602. The laser 604 receives instructions from the controller (e.g., controller 120) to hear the pre-heat cylinder to an optimal temperature for processing. The pre-heat cylinder 602 acts as a temperature controlled side wall for gas activation as well as a thermal barrier to the cold wall. During optional operation 908, the temperature of the pre-heat cylinder 602 may be optimized for substrate processing. The separate control of the active heating loop allows for the substrate 102 temperature and the gas activation temperature to be different temperatures during operation. For example, the gas activation temperature is heated to a higher temperature, about 50° C. higher, than the temperature of the substrate 102 or the temperature of the substrate support assembly 106. In one or more embodiments, optional operation 908 is performed independently from the previous operations of method 900.

The present disclosure provides a substrate processing chamber that includes an IR isolation plate having a lower isolation plate and isolation materials which are arranged to tune the thermal profile of a substrate during processing. The isolation materials allow for thermal profile tuning over the substrate processing region. Further the present disclosure provides a processing chamber configured to have a substrate disposed within a hot-wall envelope including an upper plate, a lower plate, a first sidewall, and a second sidewall defining an envelope volume. The envelope volume allows for improved film quality and growth rate for low substrate temperature processes, such as between 400° C. and 450° C., while also reducing contamination. Further, the present disclosure provides a substrate processing chamber that includes a pre-heat cylinder, which allows for decoupled control of the side wall (e.g., the pre-heat cylinder) and the substrate. Additionally, the replaceable portions of the pre-heat cylinder allows for easy process optimization.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A substrate processing chamber, comprising:
an upper body defining a processing volume;
a heat source configured to heat the processing volume;
a substrate envelope assembly disposed within the processing volume, the substrate envelope assembly comprising:
an isolation plate;
a lower envelope plate; and
sidewalls defining an envelope volume; and
a substrate support assembly configured to be disposed within the substrate envelope assembly.

2. The substrate processing chamber of claim 1, wherein the sidewalls comprise a hot wall aperture configured to allow process gases into the envelope volume.

3. The substrate processing chamber of claim 1, wherein the heat source is an infrared radiation source.

4. The substrate processing chamber of claim 3, wherein the isolation plate is configured to allow a portion of infrared radiation from the infrared radiation source into the envelope volume.

5. The substrate processing chamber of claim 3, wherein the lower envelope plate is configured to allow a portion of infrared radiation from the infrared radiation source into the envelope volume.

6. The substrate processing chamber of claim 1, wherein the isolation plate is removably coupled to the lower envelope plate by the sidewalls, the sidewalls configured to thermally isolate the envelope volume from the processing volume of the upper body.

7. The substrate processing chamber of claim 1, wherein the lower envelope plate comprises a disk of the substrate support assembly and a ring configured to contact the disk when the substrate support assembly is in an elevated processing position.

8. A substrate processing chamber, comprising:
a chamber body defining a processing volume;
a substrate support assembly disposed within the processing volume;
a heat source disposed above the substrate support assembly and coupled to the chamber body;
an isolation plate assembly disposed between the substrate support assembly and the heat source; and
a substrate envelope assembly comprising:
an isolation plate;
a lower envelope plate; and
sidewalls defining an envelope volume, the substrate support assembly disposed within the envelope volume.

9. The substrate processing chamber of claim 8, wherein the isolation plate assembly is disposed between the substrate envelope assembly and the heat source.

10. The substrate processing chamber of claim 9, wherein the sidewalls comprise a hot wall aperture configured to allow process gases into the envelope volume and wherein the sidewalls are configured to thermally isolate the envelope volume from the processing volume of the substrate processing chamber.

11. The substrate processing chamber of claim 9, wherein the isolation plate assembly comprises a lower isolation plate and a first isolation material disposed on the lower isolation plate.

12. The substrate processing chamber of claim 11, wherein the isolation plate assembly further comprises an upper isolation plate disposed above the first isolation material.

13. The substrate processing chamber of claim 11, wherein infrared radiation from the heat source passes through the isolation plate assembly and the substrate envelope assembly then into the envelope volume.

14. A substrate processing chamber, comprising:
a chamber body defining a processing volume;
a substrate support assembly disposed within the processing volume;
a heat source disposed above the substrate support assembly and coupled to the chamber body;
an isolation plate disposed between the substrate support assembly and the heat source; and
a pre-heat cylinder comprising:
a gas injection portion with one or more one or more gas delivery passages; and
a gas exhaust portion with one or more gas exhaust passages.

15. The substrate processing chamber of claim 14 further comprising:
an upper liner disposed between a sidewall of the substrate processing chamber and an upper portion of the pre-heat cylinder; and
a lower liner disposed between the sidewall of the substrate processing chamber and a lower portion of the pre-heat cylinder.

16. The substrate processing chamber of claim 14, wherein the pre-heat cylinder comprises a silicon carbide with a graphite coating.

17. The substrate processing chamber of claim 14, wherein the gas injection portion and the gas exhaust portion are removable from the pre-heat cylinder.

18. The substrate processing chamber of claim 14, wherein the pre-heat cylinder is heated by a laser.

19. The substrate processing chamber of claim 14, wherein the pre-heat cylinder, the isolation plate, and the substrate support assembly form a hot envelope.

20. The substrate processing chamber of claim 19, wherein the hot envelope is defined in an upper portion of the processing volume.
